(19) United States
(12) Patent Application Publication
(10) Pub. No.: US 2008/0057694 A1
(43) Pub. Date: Mar. 6, 2008

(54) Method for manufacturing semiconductor device

(75) Inventors: Sang Min Kim, Seoul (KR); Woo Yung Jung, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/646,699

(22) Filed: Dec. 28, 2006

(30) Foreign Application Priority Data
Sep. 6, 2006 (KR) KR 2006-85775

(51) Int. Cl. H01L 21/44

(52) U.S. Cl. 438/597

(57) ABSTRACT

A method for manufacturing a semiconductor device, in forming plugs, an alignment error margin between wirings and lower plugs is increased by using a conductive pad and thus avoids an increase of a contact resistance caused by an alignment error and improves reliability.

### BACKGROUND OF THE INVENTION

1. Field of the Invention

The invention relates to a method for manufacturing a semiconductor device and more particularly, to a method for manufacturing a semiconductor device by which an alignment error margin between a wiring and a plug formed thereunder can be increased.

2. Related Technology

FIGS. 1A to 1D are sectional views showing subsequently a method for manufacturing a semiconductor device according to the prior art.

Referring to FIG. 1A, through a conventional process, a drain select line 21d, a plurality of cell gates 21c, and a source select line 21s are formed on a cell region of the semiconductor substrate 20, and junction regions 20a to 20c are formed, respectively, therebetween. In addition, a junction region (not shown) is formed between the cell gates 21c. Meanwhile, a transistor gate 21g and junction regions 20d, 20e are formed on a peripheral circuit region. In addition, on the whole structure, a first interlayer insulating film 22 is formed and a source contact plug 23 is formed on the junction region 20b where the first interlayer insulating film 22 is etched. Again, a second interlayer insulating film 24 is formed on the whole structure including the source contact plug 23, and a first hard mask that exposes a drain contact plug 26a on the cell region and a contact plug region 26b on the peripheral circuit region, is formed over the second interlayer insulating film 24.

Referring to FIG. 1B, the lower second interlayer insulating film 24 and first interlayer insulating film 22 are etched subsequently by using the first hard mask 24 (see FIG. 1) as an etching mask such that the junction regions 20a, 20e on the cell region and peripheral circuit region are exposed. In addition, the conductive material such as metal or polysilicon, etc., is filled into the space where the first and second interlayer insulating films 22, 24 are removed, to simultaneously form the drain contact plug 27a on the cell region and the contact plug 27b on the peripheral circuit region.

Then, the hard mask 25 (see FIG. 1) is removed to subsequently form a third interlayer insulating film 28 and a second hard mask 29. In addition, the predetermined region of the third interlayer insulating film 28 is etched by using the second hard mask 29 as an etching mask to form a bit line trench 30a, a source trench 30b, and a well pick up trench 30c on the cell region, and a trench 30e that exposes the well pick up trench 30d and contact plug 27b on the peripheral circuit region.

Referring to FIG. 1C, a photoresist pattern 31 is formed on the upper part of the whole structure including the second hard mask 29 and the predetermined regions of the second interlayer insulating film 24 and first interlayer insulating film 22 are subsequently etched by an etching process using the photoresist pattern 31 as an etching mask. As a result, a source pick up contact hole 32a and a well pick up contact hole 32b, which expose the source contact plug 23, are formed on the cell region and a well pick up contact hole 32c that exposes the junction region 20d is formed on the peripheral circuit region.

Referring to FIG. 1D, the photoresist pattern 31 (see FIG. 1C) and second hard mask 29 (see FIG. 1C) are removed and then conductive material is filled into the trench and the contact hole to form a wiring for a bit line 33a, a wiring for a source line 33b, wirings for well pick up 33c, 33d and a metal wiring 33e.

Here, since the widths of the plugs that are formed in the manner described above are significantly narrow, an alignment margin with the wirings that are formed on the plugs in the following processes is very important. In particular, in the case where the bit line has a single page buffer, since it has more bit line page buffer patterns, the alignment margin between the wirings and lower plugs is further decreased such that resistance may be increased or failure may be caused due to an alignment error.

### SUMMARY OF THE INVENTION

The invention has been proposed to solve the above drawbacks, and relates to increasing an alignment between wirings and lower plugs by using a conductive pad in forming plugs and thus avoid an increase of a contact resistance caused by an alignment error.

A method for manufacturing a semiconductor device according to the invention may include the steps of providing a semiconductor substrate on which a cell region and a peripheral circuit region are separately formed, and a plurality junction regions are formed, forming a first interlayer insulating film on the semiconductor substrate, forming a first contact hole on a first junction region among the plurality of junction regions by etching a predetermined region of the first interlayer insulating film, forming a first contact plug on the inside of the first contact hole, forming a conductive pad having wider area than the first contact plug over the first contact plug, forming a second interlayer insulating film on the whole structure including the conductive pad, etching a predetermined region of the first and second interlayer insulating film such that the second contact hole is formed over a second junction region among the plurality of junction regions and on the second conductive pad, and forming a second contact plug in the second contact hole.

The step of forming the conductive pad preferably includes forming a third interlayer insulating film on the whole structure including the first contact plug, etching the third interlayer insulating film over the first contact plug, and filling conductive material into the part where the third interlayer insulating film is removed.

The step of forming the conductive pad preferably includes a step of forming a dummy conductive pad on a region where the first contact plug is not formed.

In one embodiment, a method for manufacturing a semiconductor device according to the invention may further include a step of forming metal wiring on the second contact plug, after forming the second contact plug.

The first junction region preferably includes a source junction region and a well pick up region on the cell region, and a junction region on the peripheral circuit region, and the second junction region preferably includes a drain junction region on the cell region.

Before forming the first interlayer insulating film, a drain select line, a plurality of memory cell gates, and a source select line are preferably further formed on the cell region of the semiconductor substrate, and a transistor gate is preferably further formed on the peripheral circuit region of the semiconductor substrate.

The first interlayer insulating film is preferably formed in a thickness of 5000 Å-10000 Å by using HDP oxidation film, and the second interlayer insulating film and third interlayer insulating film to preferably formed in a thickness of 1000 Å-5000 Å by using a HDP oxidation film or PE-TEOS (Plasma Enhanced Tetra Ethyl OrthoSilicate) oxidation film.

The etching processes of the first to third interlayer insulating films are preferably performed with a selection ratio of 5:1-20:1, at a pressure of 15 mTorr-40 mTorr, a temperature of 20° C.-40° C. and a bottom power of 1000 W-1500 W, and one or more of CF₄, CₓH_{y}F_{z}, where x is 1 to 5, y is 0 to 3, and z is 1 to 8, Ar, and O₂ is preferably used as an etchant.

The conductive pad is preferably formed of metal or polysilicon.

### BRIEF DESCRIPTION OF THE DRAWINGS

The following drawings, which are included to provide a further understanding of the invention and are incorporated in and constitute a part of this specification, illustrate embodiments of the invention and together with the description serve to explain the principles of the invention.

FIGS. 1A to 1D are sectional views showing subsequently a method for manufacturing a semiconductor device according to the prior art; and

FIGS. 2A to 2D are sectional views showing subsequently a method for manufacturing a semiconductor device according to the invention.

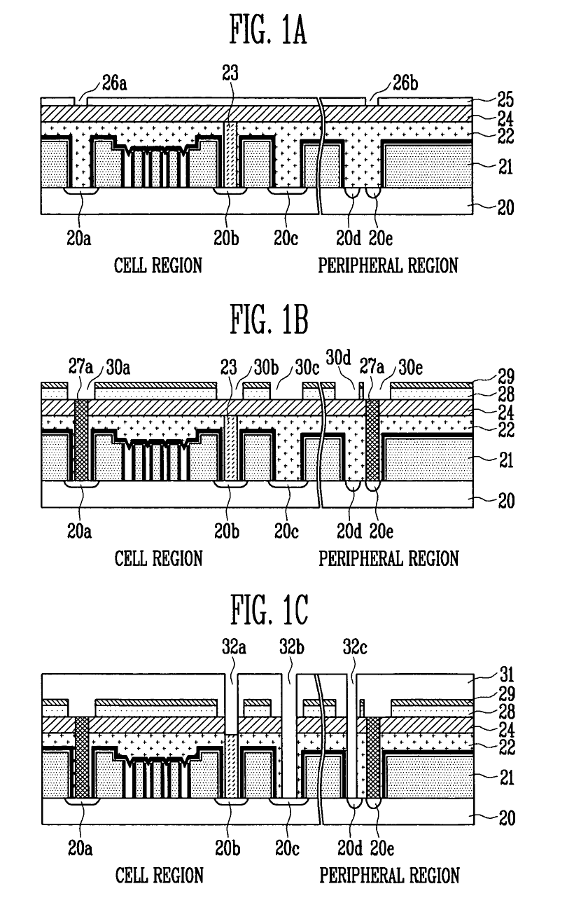

### DESCRIPTION OF SPECIFIC EMBODIMENTS

In the following, preferred embodiments of the invention will be described in conjunction with the accompanying drawings. However, both the foregoing general description and the following detailed description are exemplary and are intended to provide further explanation of the invention as claimed.

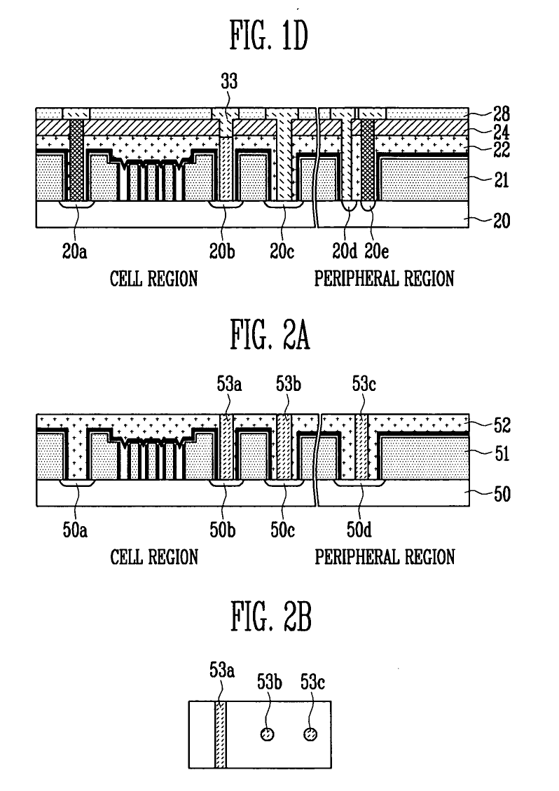

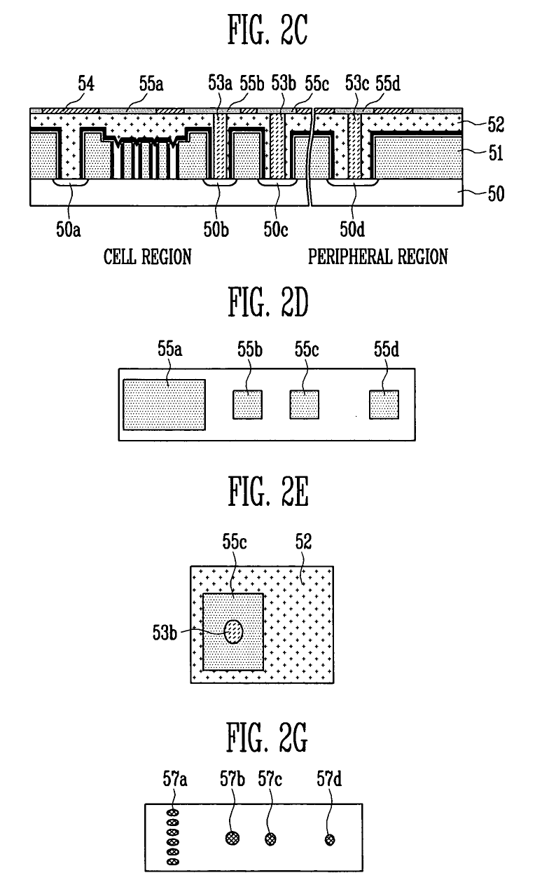

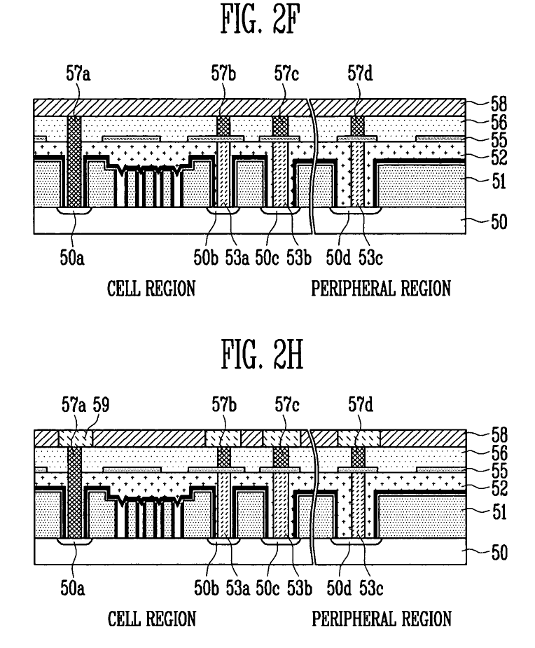

FIGS. 2A to 2D are sectional views showing a method for manufacturing a semiconductor device according to the invention.

Referring to FIG. 2A, through any suitable process, a drain select line 51d, a plurality of memory cell gates 51c, and a source select line 51s are formed on a cell region of the semiconductor substrate 50, and a drain region 50a, a source region 50b, and a well pick up region 50c are formed, respectively, therebetween. In addition, a junction region (not shown) is formed between the cell gates 51c. Meanwhile, a transistor gate 51g and a junction region 50d are formed on an peripheral circuit region. In addition, on the whole structure, a first interlayer insulating film 52 is formed. Then, the interlayer insulating film 52 under which the source region 50b and well pick up region 50c are disposed on the cell region, and the junction region 50d is disposed on the peripheral circuit region, is selectively etched to form, respectively, a first source contact plug 53a, a first well pick up plug 53b and a first contact plug 53c. Here, the first source contact plug 53a is formed as a line form.

In conjunction with the configurations of the aforementioned elements, the first interlayer insulating film 52 may be formed of arbitrary material having dielectric characteristics; however, preferably, it may formed of an HDP oxidation film of 5000 Å-10000 Å. In addition, in etching the first interlayer insulating film 52, the etching process may preferably be performed with a selection ratio of 5:1-20:1, at a pressure of 15 mTorr-40 mTorr, a temperature of 20° C.-40° C. and a bottom power of 1000 W-1500 W. At this time, one or more of CF₄, CₓH_{y}F_{z}, where x is 1 to 5, y is 0 to 3, and z is 1 to 8, Ar, and O₂ is preferably used as an etchant. CₓH_{y}F_{z}, may be, for example, CF₄, C₄F₆, CH₂F₂, C₃F₈, CHF₃, C₄F₈, C₅F₆, C₂F₆, CH₃F, etc.

Referring to FIG. 2B, a second interlayer insulating film 54 is formed over the aforementioned structure. In addition, the second interlayer insulating film 54 over the plugs 53a to 53c is selectively etched. As a result, the plugs 53a to 53c formed over the semiconductor substrate 50 are exposed. At this time, to expose the first interlayer insulating film adjacent to the plugs 53a to 53c, the areas of the second interlayer insulating film 54 that are wider than the upper surface areas of the plugs 53a to 53c, are removed. Then, conductive material is filled into the part where the second interlayer insulating film is removed.

As the conductive material, conventional material used in a semiconductor process may be used, and preferably metal such as tungsten or polysilicon, etc., is used. As a result, contact pick up pads 55b, 55d and a well pick up pad 55c (see FIG. 2c) are formed over the plugs 53a to 53c, respectively, and these pads 55b to 55d are electrically connected to the plugs 53a to 53c formed thereunder. In addition, in such region where a plug is not formed as the region where the cell gate 51c is formed, a dummy pad 55a may be formed. The dummy pad 55a functions as an etching-interference film in the following process and avoids an excessive etching of the lower layer.

In conjunction with the configurations of the aforementioned elements, the pads 55b to 55d function to increase the upper surface of the plugs 53a to 53c formed thereunder. Accordingly, the contact area with contact plugs or metal wirings to be formed in later is increased and thus a alignment margin is increased, thereby avoiding an increase of a resistance or a failure, caused by an alignment error.

In conjunction with the configurations of the aforementioned elements, the second interlayer insulating film 54 may be formed of any suitable material having dielectric characteristics; however, preferably, it may formed of an HDP oxidation film or PE-TEOS (Plasma Enhanced Tetra Ethyl OrthoSilicate) of 1000 Å-5000 Å. In addition, in etching the second interlayer insulating film 54, the etching process is preferably performed with a selection ratio of 5:1-20:1, at a pressure of 15 mTorr-40 mTorr, a temperature of 20° C.-40° C. and a bottom power of 1000 W-1500 W. At this time, one or more of CF₄, CₓH_{y}F_{z}, where x is 1 to 5, y is 0 to 3, and z is 1 to 8, Ar, and O₂ is preferably used as an etchant.

Referring to FIG. 2C, a third interlayer insulating film 56 is formed over the whole structure including the pads 55b to 55d. Then, the predetermined region of the third interlayer insulating film 56, second interlayer insulating film 54 and first interlayer insulating film 52 over the drain region 50a, source region 50b, well pick up region 50c, and junction region 50d, is etched. At this time, in the region where the pads 55b to 55d are not formed, all of the third interlayer insulating film 56, second interlayer insulating film 54 and first interlayer insulating film 52 are etched to expose the drain region 50a. However, over the source region 50b, well pick up region 50c, and junction region 50d, the second interlayer insulating film 54 and first interlayer insulating film 52 are not etched with the pads 55b to 55d, and only the third interlayer insulating film 56 is etched to expose a region of the pads 55b to 55d. As a result, a drain contact hole is formed over the drain region 50a and a source contact hole is formed on the pad 55b over the well pick up region 50c, and a contact hole is formed on the pad 55d over the junction region 50d. In a subsequent step, conductive material is filled into the insides of these holes to form a drain contact hole 57a, a second source contact hole 57b, a second well pick up hole 57c, and a second contact plug 57d. Then, a fourth interlayer insulating film 58 is formed on whole structure.

In conjunction with the configurations of the aforementioned elements, the third interlayer insulating film 56 is preferably formed of arbitrary material having dielectric characteristics; however, preferably, it may formed of an HDP oxidation film or PE-TEOS (Plasma Enhanced Tetra Ethyl OrthoSilicate) of 1000 Å-5000 Å. In addition, in etching the second interlayer insulating film 56, the etching process may be preferably performed with a selection ratio of 5:1-20:1, at a pressure of 15 mTorr-40 mTorr, a temperature of 20° C.-40° C. and a bottom power of 1000 W-1500 W. At this time, one or more of CF₄, CₓH_{y}F_{z}, where x is 1 to 5, y is 0 to 3, and z is 1 to 8, Ar, and O₂ is preferably used as an etchant.

Referring to FIG. 2D, the fourth interlayer insulating film 58 over the drain contact plug 57a, second source contact plug 57b, second well pick up plug 57c and second contact plug 57d, is selectively etched. As a result, the plugs 57a to 57d are exposed. Then, conductive material is filled into the etched-region of the fourth interlayer insulating film 58 to form the wiring 59.

According to the invention, in forming plugs, an alignment error margin between wirings and lower plugs is increased by using a conductive pad and thus at an increase of a contact resistance caused by an alignment error is provided and reliability is improved.

What is claimed is:

1. A method for manufacturing a semiconductor device including the steps of:
providing a semiconductor substrate on which a cell region and an peripheral circuit region are separately formed, and a plurality of junction regions are formed;
forming a first interlayer insulating film on the semiconductor substrate;
forming a first contact hole on a first junction region selected from the plurality of junction regions by etching a predetermined region of the first interlayer insulating film;
forming a first contact plug on the inside of the first contact hole;
forming a conductive pad having wider area than the first contact plug over the first contact plug;
forming a second interlayer insulating film on the whole structure including the conductive pad;
etching a predetermined region of the first and second interlayer insulating films such that the second contact hole is formed over a second junction region among the plurality of junction regions and on the second conductive pad; and
forming a second contact plug in the second contact hole.

2. A method for manufacturing a semiconductor device according to claim 1, wherein the step of forming the conductive pad includes:
forming a third interlayer insulating film on the whole structure including the first contact plug;
etching the third interlayer insulating film over the first contact plug; and
filling conductive material into an area where the third interlayer insulating film is removed.

3. A method for manufacturing a semiconductor device according to claim 1, wherein the step of forming the conductive pad further includes a step of forming a dummy conductive pad on a region where the first contact plug is not formed.

4. A method for manufacturing a semiconductor device according to claim 1, further including a step of forming metal wiring on the second contact plug, after forming the second contact plug.

5. A method for manufacturing a semiconductor device according to claim 1, wherein the first junction region includes a source junction region and a well pick up region on the cell region, and a junction region on the peripheral circuit region, and the second junction region includes a drain junction region on the cell region.

6. A method for manufacturing a semiconductor device according to claim 1, comprising a step, before forming the first interlayer insulating film, of further forming a drain select line, a plurality of memory cell gates, and a source select line on the cell region of the semiconductor substrate, and further forms a transistor gate on the peripheral circuit region of the semiconductor substrate.

7. A method for manufacturing a semiconductor device according to claim 1, comprising forming the first interlayer insulating film in a thickness of 5000 Å-10000 Å by using high density plasma (HDP) oxidation film.

8. A method for manufacturing a semiconductor device according to claim 1, comprising forming the second interlayer insulating film in a thickness of 1000 Å-5000 Å by using a high density plasma (HDP) oxidation film or a PE-TEOS (Plasma Enhanced Tetra Ethyl OrthoSilicate) oxidation film.

9. A method for manufacturing a semiconductor device according to claim 2, comprising forming the third interlayer insulating film in a thickness of 1000 Å-5000 Å by using a high density plasma (HDP) oxidation film or a PE-TEOS (Plasma Enhanced Tetra Ethyl OrthoSilicate) oxidation film.

10. A method for manufacturing a semiconductor device according to claim 1, comprising performing the etching processes of the first interlayer insulating film and second interlayer insulating film with a selection ratio of 5:1-20:1, at a pressure of 15 mTorr-40 mTorr, a temperature of 20° C.-40° C. and a bottom power of 1000 W-1500 W, and, using at least one member selected from the group consisting of CF₄, CₓH_{y}F_{z}, where x is 1 to 5, y is 0 to 3, and z is 1 to 8, Ar, and O₂ as an etchant.

11. A method for manufacturing a semiconductor device according to claim 2, comprising performing the etching process of the third interlayer insulating film with a selection ratio of 5:1-20:1, at a pressure of 15 mTorr-40 mTorr, a temperature of 20° C.-40° C. and a bottom power of 1000 W-1500 W, and using at least one member selected from the group consisting of CF₄, CₓH_{y}F_{z}, where x is 1 to 5, y is 0 to 3, and z is 1 to 8, Ar, and O₂ as an etchant.

12. A method for manufacturing a semiconductor device according to claim 1, wherein the conductive pad is formed of metal or polysilicon.
